(19) United States
(12) Patent Application Publication
(10) Pub. No.: US 2006/0292462 A1
(43) Pub. Date: Dec. 28, 2006

(54) Nir absorption and color compensating compositions

(76) Inventors: Hwi Min Seo, Gunpo-Si (KR); Lee Hwa Song, Gwangmycong-Si (KR); Soo Jeong Lee, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/455,247

(22) Filed: Jun. 15, 2006

(30) Foreign Application Priority Data
Jun. 27, 2005 (KR) 10-2005-0055699

(51) Int. Cl. G03F 1/00

(52) U.S. Cl. 430/7

(57) ABSTRACT

Disclosed herein is a composition for use as a film on an image display filter. In some embodiments, the composition includes a cyanine dye exhibiting an absorption maximum in the wavelength region from about 830 to about 880 nm or from about 580 to about 600 nm and an anthraquinone dye comprising an anthraquinone compound substituted with an amino group in one or more positions selected from the 1-, 4-, 5-, and 8-position.

### CROSS-REFERENCE TO RELATED APPLICATIONS

This non-provisional application claims priority under 35 U.S.C. §119(a) to Korean Patent Application No. 2005-55699 filed on Jun. 27, 2005, which is herein incorporated by reference.

### BACKGROUND

1. Field

The present invention relates to a near-infrared absorbing and color compensation film composition for use in displays, such as plasma displays.

2. Description of the Related Technology

Plasma displays are self-emissive displays, and have advantages of large display area and small thickness. Because of these advantages, plasma displays have been used for large-screen televisions. In plasma displays, discharge gases generate ultraviolet (UV) rays to excite phosphors to emit light. During operation, considerable amounts of near-infrared rays are emitted from the plasma display.

A wavelength range of the near-infrared region overlaps with a wavelength band around 930 nm which is employed in many remote controllers used for household electronic devices. Accordingly, near-infrared rays generated from a plasma display may cause malfunctions or undesired operation in household electric appliances. Further, near-infrared rays generated from plasma displays may affect certain wavelength ranges of around 850 nm which are employed in infrared data communication. Accordingly, filters capable of efficiently blocking near-infrared rays in the range of 820 nm to 1,000 nm may be needed to block unwanted near-infrared rays emitted from plasma displays.

On the other hand, the color purity of red light emitted from phosphors of plasma displays drops considerably due to strong light emission in the vicinity of 590 nm. Due to the presence of neon gas, which is a major constituent of penning gases for exciting phosphors, orange neon light is always emitted at about 585 nm, regardless of colors generated from the phosphors. Accordingly, color compensation filters capable of selectively absorbing light in the range of 580 nm to 600 nm may be needed to reduce the emission of orange neon light and obtain more natural colors.

In addition to near-infrared blocking filters and color compensation filters, electromagnetic wave shielding filters may be needed to efficiently block large amounts of electromagnetic waves generated from plasma displays. Furthermore, since external light may be reflected on reflective materials in plasma displays, it may be necessary to form an antireflective layer on the front surface of a display.

A front filter for a plasma display is configured to have near-infrared blocking, electromagnetic wave shielding, color compensation and antireflective functions. Such a front filter is prepared by laminating functional coating films, an adhesive layer, a protective film and a release film sequentially on a base film.

The release film and the protective film are removed after the lamination is completed. If more than one function of the films can be integrated in a single film, the amount of the release film and the protective film would be reduced. The adhesive layer is used to laminate the respective films. If the number of necessary films is decreased, the amount of the adhesive material will also be reduced. In addition, if the multiple functions are integrated in a single film, the base film may be omitted.

In this connection, many have attempted to decrease the number of films used to manufacture a filter for plasma displays. Methods for incorporating functional layers, e.g., a near-infrared absorbing layer and a color compensation layer, into an adhesive coating layer have been suggested as particularly promising methods.

### SUMMARY OF THE INVENTION

Described herein are compositions for use as films to block certain wavelengths of light transmission. In some embodiments, the compositions may be to block certain wavelengths emitted from display devices.

One embodiment of a composition comprises a cyanine dye exhibiting an absorption maximum in the wavelength region from about 830 to about 880 nm or from about 580 to about 600 nm, and an anthraquinone dye comprising an anthraquinone compound represented by Formula (I):

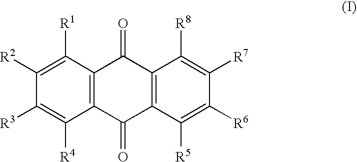

In Formula (I), at least one of R¹, R⁴, R⁵, and R⁸ is NR⁹₂. R², R³, R⁶ and R⁷ are independently hydrogen, halogen, C₁-C₂₀ alkyl, C₁-C₂₀ alkyoxy, aryl, or aryloxy. R⁹ is independently hydrogen, C₁-C₂₀ alkyl, or aryl. In some embodiments, when each of R¹, R⁴, R⁵, and R⁸ is not NR⁹₂, each is hydrogen.

In some embodiments, the anthraquinone dye comprises one or more anthraquinone compounds having Formula (I). In certain embodiments, the anthraquinone dye comprises one or more anthraquinone compounds substituted to achieve a color balance in the composition. In some embodiments, the anthraquinone compound is selected from a group consisting of 1,4-bis(isopropylamino)anthracene-9,10-dione, 1,4-bis(p-tolylamino)anthracene-9,10-dione, 1,4-diamino-2,3-dichloroanthracene-9,10-dione, 1,4-diamino-2,3-diphenoxyanthracene-9,10-dione, and 1-aminoanthracene-9,10-dione

In some embodiments, the cyanine dye may have a maximum absorbance of wavelengths ranging from about 830 to about 880 nm. In one embodiment, the cyanine dye is represented by Formula (II)

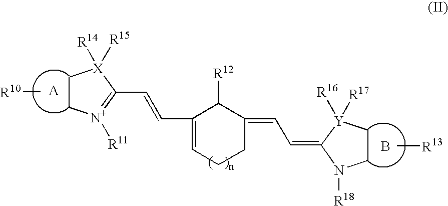

In Formula (II), R¹⁰ and R¹³ are independently hydrogen, halogen, nitro, cyano, C₁-C₂₀ alkoxy, C₁-C₂₀ alkyl, alkyl alkoxy, or amino. R¹¹ and R¹⁸ are independently hydrogen, C₁-C₂₀ alkyl, alkyl alkoxy, or alkyl sulfonic. R¹² is hydrogen, halogen, substituted phenyl, C₁-C₂₀ alkyl, or amino. R¹⁴, R¹⁵, R¹⁶, and R¹⁷ are independently hydrogen, C₁-C₂₀ alkyl, or cyclic alkyl. In some embodiments, R¹⁴ and R¹⁵ or R¹⁶ and R¹⁷ are connected through a membered ring comprising three or more carbon atoms. A and B are independently phenyl, napthyl, or anthracenyl. X and Y are independently C, N, S or Se. In embodiments when X or Y is N, then R¹⁵ or R¹⁷ is not present. In embodiments when X or Y is S or Se, then R¹⁴, R¹⁵, R¹⁶, or R¹⁷ is not present. In certain embodiments, n is 0, 1 or 2.

In other embodiments, the cyanine dye may comprise a compound represented by Formula (III):

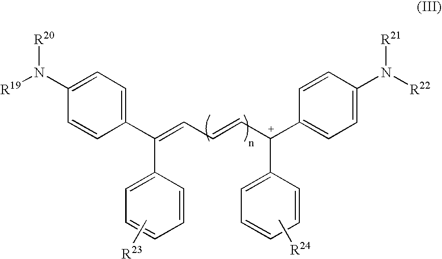

In Formula III, R¹⁹, R²⁰, R²¹, and R²² are independently hydrogen. C₁-C₂₀ alkyl, C₁-C₂₀ alkoxy, alkyl alkoxy group, or cyclic alkyl. In some embodiments, R¹⁹ and R²⁰ or R²¹ and R²² are connected through a membered ring comprising three or more carbon atoms. R²³ and R²⁴ are independently hydrogen, halogen, nitro, cyano, C₁-C₂₀ alkoxy, C₁-C₂₀ alkyl, alkyl alkoxy, or amino, and n is 0, 1, 2, 3 or 4.

A cyanine dye may also have a maximum absorbance of wavelengths of light ranging from about 580 to about 600 nm. In some embodiments, the cyanine dye may be represented by the Formula (IV):

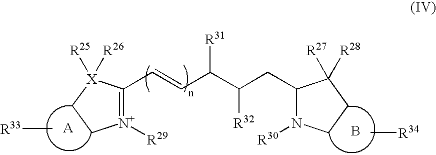

In Formula (IV), R³³ and R³⁴ are independently hydrogen, halogen, nitro, cyano, C₁-C₂₀ alkoxy, C₁-C₂₀ alkyl, alkyl alkoxy, or amino. R²⁹ and R³⁰ are independently hydrogen, C₁-C₂₀ alkyl, alkyl alkoxy, or alkylsulfonic acid group. In embodiments, n is 0 or 1. In some embodiments when n is 0, R³¹ is a hydrogen atom, and R³² is hydrogen, halogen, aryl, C₁-C₂₀ alkyl, or amino. In other embodiments, when n is 1, R³¹ is hydrogen, halogen, aryl, C₁-C₂₀ alkyl, or amino, and R³² is hydrogen. A and B may be independently phenyl, napthyl, or anthracenyl. X and Y may be independently C, N, S, or Se. In embodiments when X or Y is C, then R²⁵, R²⁶, R²⁷, or R²⁸ is independently hydrogen, C₁-C₂₀ alkyl or cyclic alkyl. In some embodiments, R²⁵ and R²⁶ or R²⁷ and R²⁸ are connected through a membered ring comprising three or more carbon atoms. In some embodiments when X or Y is N, then R²⁶ or R²⁸ are not present and R²⁵ and R²⁶ are independently hydrogen or C₁-C₂₀ alkyl. In some embodiments, when X or Y is S or Se, then R¹ and R² or R³ and R⁴ are not present.

In some embodiments, the cyanine dye comprises a compound having the following Formula (V):

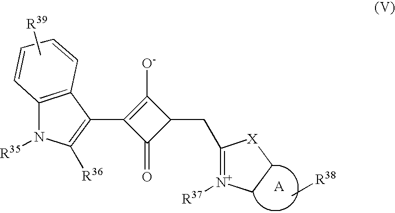

In Formula (V), A is independently phenyl or napthyl. R³¹ and R³⁷ are independently hydrogen, C₁-C₂₀ alkyl, alkyl alkoxy, or an alkylsulfonic acid group. R³⁶ is hydrogen, C₁-C₂₀ alkyl, phenyl, or alkyl alkoxy. R³⁸ and R³⁹ are independently hydrogen, halogen, nitro, cyano, C₁-C₂₀ alkyl, C₁-C₂₀ alkoxy, or alkyl alkoxy.

In some embodiments, the cyanine dye comprises a compound having Formula (VI):

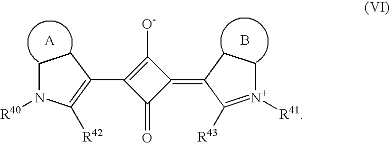

In Formula (VI), A and B are independently phenyl or napthyl. R⁴⁰ and R⁴¹ are independently hydrogen, C₁-C₂₀ alkyl, or alkyl alkoxy. R⁴² and R⁴³ are independently hydrogen, C₁-C₂₀ alkyl, phenyl, or alkyl alkoxy.

In some embodiments, the composition may additionally comprise a dye exhibiting an absorption maximum in the wavelength region from about 950 to about 1100 nm. In some of these embodiments, the dye exhibiting an absorption maximum in the wavelength region from about 950 to about 1100 nm comprises a diimmonium dye.

Some embodiments of the composition may further comprise a toning dye. Embodiments may also comprise a binder resin and a solvent.

In some embodiments, the composition may be formed in a layer on a substrate. In some embodiments, the composition may be used in combination with a filter, or coated on a filter. In some embodiments, the filter is for a display device. In some embodiments, the filter comprises the composition as described herein.

In one embodiment, an electronic device comprises a display configured to display a visible image and a film covering at least part of the display. The film may comprise embodiments of the composition as described herein. One embodiment includes a method of displaying an image using the electronic device which comprises providing the electronic device, stimulating the electronic device so as to emit near infrared light from the display. In certain embodiments, at least part of the near infrared light emitted from the display is absorbed in the film. In some embodiments, the electronic device is configured to further emit orange light having a wavelength of about 580 nm to about 600 nm and the filter is configured to further absorb at least part of the orange light.

Another embodiment is a method of preventing the malfunction of electronic devices that operate in accordance with a wireless signal carried by near infrared light. The method may comprise providing a display device emitting near infrared light, wherein the display device comprises a display surface and covering at least part of the display surface with a filter comprising a composition as described herein. In some embodiments, the filter absorbs at least part of the near infrared light that causes the malfunction of an electronic device.

In some of the embodiments as described herein, the electronic device is selected from the group consisting of a DVD player, a CD player, a remote control, a DVR recorder, a stereo system, and a microwave oven. In some embodiments, the display device comprises a plasma display device.

### BRIEF DESCRIPTION OF THE DRAWINGS

The above and other features and advantages of the present invention will be more clearly understood from the following detailed description taken in conjunction with the accompanying drawings, in which:

FIG. 1 is a transmission spectrum measured before and after the light resistance test of a color compensation film for image display apparatus of Example 1 at 0.06 wt % and 0.12 wt % of 1,4-diaminoanthraquinone dye;

FIG. 2 is a transmission spectrum measured before and after the light resistance test of a color compensation film for image display apparatus of Example 2 at 0.06 wt % and 0.12 wt % of 1,4-diaminoanthraquinone dye;

FIG. 3 is a transmission spectrum measured before and after the light resistance test of an NIR absorption film for image display apparatus of Example 3 at 0.06 wt % of 1,4-diaminoanthraquinone dye;

FIG. 4 is a transmission spectrum measured before and after the light resistance test of an NIR absorption and color compensating film for image display apparatus of Example 4;

FIG. 5 is a transmission spectrum measured before and after the light resistance test of an NIR absorption and color compensating film for image display apparatus of Example 5;

FIG. 6 is a transmission spectrum measured before and after the light resistance test of a NIR absorption and color compensating film for image display apparatus of Example 6;

FIG. 7 is a transmission spectrum measured before and after the light resistance test of a film for image display apparatus of Comparative Example 1 at 0.06 wt % and 0.12 wt % of perynone dye;

FIG. 8 is a transmission spectrum measured before and after the light resistance test of a film for image display apparatus of Comparative Example 2 at 0.10 wt % 2-aminoanthraquinone; and

FIG. 9 is a transmission spectrum measured before and after the light resistance test of a film for image display apparatus of Comparative Example 3 at 0.08 wt % of 1,4-dihydroxyanthraquinone.

### DETAILED DESCRIPTION OF EMBODIMENTS

Described herein are compositions comprising dyes that can be used to absorb certain wavelengths of light. Some wavelengths which may be absorbed correspond to near infrared light. Other wavelengths which are absorbed correspond to visible light. Other wavelengths which can be absorbed by some dyes correspond to ultraviolet light. In any one embodiment, more than one range of wavelengths can be absorbed including from about 580 to about 600 nm, from about 830 to about 880 nm, and about 1050 to about 1100 nm.

Near-infrared absorbing colorants include anthraquinone, phthalocyanine, cyanine, dithiol-metal complex, and diimmonium colorants. However, due to their very low absorbance, they must be used in amounts sufficient to block near-infrared rays. Further, some colorants can be mixed with adhesives. For example, phthalocyanine colorants have a high absorbance and are not decomposed by functional groups of adhesives. However, since some colorants have a narrow absorption range, they must be used with one or more other colorants having different absorption wavelength bands in order to absorb light in a broad range of wavelengths. In addition, the use of large amounts of the colorants may increase costs and may cause low visible light transmittance.

In some embodiments, a composition as described herein, comprises a cyanine dye and an amino anthraquinone dye. In some embodiments, the cyanine dye is selected from one or more dyes having a maximum absorbance at a wavelength range from about 830 to about 880 nm or a maximum absorbance at a wavelength range from about 580 to about 600 nm.

In some embodiments, a composition comprises at least one dye having a maximum absorbance of about 830 nm to about 880 nm. These wavelengths correspond to the dye having NIR absorption characteristic. In some embodiments, the dye with a maximum absorbance of about 830 to about 880 nm comprises phthalocyanine dyes and/or cyanine dyes. Examples of cyanine dyes having a maximum absorbance at a wavelength of about 830 to about 880 nm are represented by Formulas (II) and (III) below:

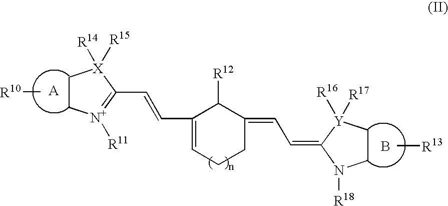

In Formula II, R¹⁰ and R¹³ are independently hydrogen, halogen, nitro, cyano, C₁-C₂₀ alkoxy, C₁-C₂₀ alkyl, alkyl alkoxy, or amino. Each of R¹¹ and R¹⁸ is independently hydrogen, C₁-C₂₀ alkyl, alkyl alkoxy, or alkyl sulfonic. R¹² is hydrogen, halogen, substituted phenyl, C₁-C₂₀ alkyl, or amino. R¹⁴, R¹⁵, R¹⁶, and R¹⁷ are independently hydrogen, C₁-C₂₀ alkyl, or cyclic alkyl whereby R¹⁴ and R¹⁵ or R¹⁶ and R¹⁷ are connected through a membered ring comprising three or more carbon atoms. Each of A and B is independently phenyl, napthyl, or anthracenyl. Each of X and Y is independently C, N, S or Se. When X or Y is N, then R¹⁵ or R¹⁷ is not present. When X or Y is S or Se, then R¹⁴, R¹⁵, R¹⁶, or R¹⁷ is not present. Also, n is 0, 1 or 2.

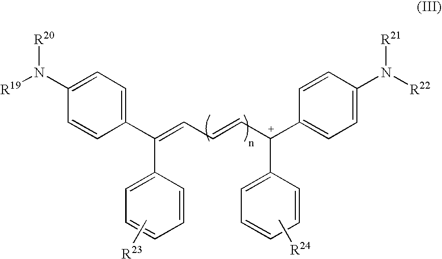

In Formula (III), each of R¹⁹, R²⁰, R²¹, and R²² is independently hydrogen, C₁-C₂₀ alkyl, C₁-C₂₀ alkoxy, alkyl alkoxy group, or cyclic alkyl. In some embodiments, R¹⁹ and R²⁰ are connected through a membered ring comprising three or more carbon atoms. In some embodiments, R²¹ and R²² are connected through a membered ring comprising three or more carbon atoms. Each of R²³ and R²⁴ is independently hydrogen, halogen, nitro, cyano, C₁-C₂₀ alkoxy, C₁-C₂₀ alkyl, alkyl alkoxy, or amino. Also, n is 0, 1, 2, 3 or 4.

Such near-infrared absorbing cyanine colorants are commercially available under trademarks, for example, TZ-115 (Asahi Denka), NK-7916 (Hayashibara biochemical), PDC-400 (Nippon Kayaku) and PD-301 (Yamada Chemical). These commercially available colorant cations are typically ionically bonded to halogen anions, ClO₄⁻, PF₆⁻, SbF₆⁻, BF₄⁻, or toluene sulfonate anions.

In some embodiments, the dye having a maximum absorbance of about 830 nm to about 880 nm is used in an amount of about 0.02 to about 0.1 wt %, based on the total weight of the composition, which includes the anthraquinone dye, the cyanine dye, the binder resin and the solvent. However, other embodiments comprise about 0.04 to about 0.08 wt % of the dye having a maximum absorbance of about 830 nm to about 880 nm, based on the total weight of the composition. In other embodiments, the composition comprises about 0.05 to about 0.09 wt % of the dye having a maximum absorbance of about 830 nm to about 880 nm, based on the total weight of the composition. Some embodiments comprise about 0.005, 0.006, 0.007, 0.008, 0.009, 0.010, 0.012, 0.014, 0.016, or 0.018 wt % of the dye having a maximum absorbance of about 830 nm to about 880 nm, based on the total weight of the composition. In other embodiments, the composition comprises more than about 0.1 wt %, of the dye having a maximum absorbance of about 830 nm to about 880 nm, including about 0.11, 0.12, 0.13, 0.14, 0.15, 0.16, 0.17, 0.18, 0.19, or 0.20 wt %, based on the total weight of the composition.

In some embodiments, the composition comprises at least one dye having maximum absorbance at a wavelength ranging from 580 to 600 nm. In some embodiments, the at least one dye having maximum absorbance at a wavelength ranging from 580 to 600 nm comprises one or more selected from the group consisting of cyanine dyes or tetraazaporphyrin dyes. Examples of cyanine dyes having a maximum absorabance at a wavelength of about 830 to about 880 nm are represented by Formulas (IV), (V), and (VI) below.

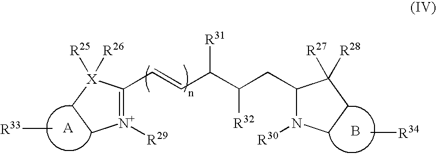

In Formula (IV), R³³ and R³⁴ are independently hydrogen, halogen, nitro, cyano, C₁-C₂₀ alkoxy, C₁-C₂₀ alkyl, alkyl alkoxy, or amino. R²⁹ and R³⁰ are independently hydrogen, C₁-C₂₀ alkyl, alkyl alkoxy, or alkylsulfonic acid group. In some embodiments, n is 0 or 1. When n is 0, R³¹ is a hydrogen atom, and R³² is hydrogen, halogen, aryl, C₁-C₂₀ alkyl, or amino. When n is 1, R³¹ is hydrogen, halogen, aryl, C₁-C₂₀ alkyl, or amino, and R³² is hydrogen. A and B are independently phenyl, napthyl, or anthracenyl. X and Y are independently C, N, S, or Se. When X or Y is C, then R²⁵, R²⁶, R²⁷, and R²⁸ are independently hydrogen, C₁-C₂₀ alkyl, or cyclic alkyl, where R²⁵ and R²⁶ or R²⁷ and R²⁸ may be connected through a membered ring comprising three or more carbon atoms. When X or Y is N, then R²⁶ or R²⁸ is not present, and R²⁵ and R²⁶ are independently hydrogen or C₁-C₂₀ alkyl. When X or Y is S or Se, then R²⁵ and R²⁶ or R²⁷ and R²⁸ are not present.

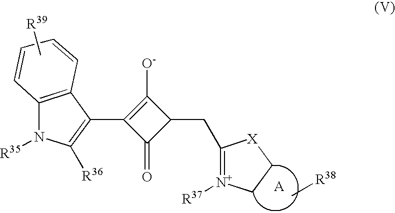

In Formula (V), A is independently phenyl or napthyl. R³⁵ and R³⁷ are independently hydrogen, C₁-C₂₀ alkyl, alkyl alkoxy, or an alkylsulfonic acid group. R³⁶ is hydrogen, C₁-C₂₀ alkyl, phenyl, or alkyl alkoxy. R³⁸ and R³⁹ are independently hydrogen, halogen, nitro, cyano, C₁-C₂₀ alkyl, C₁-C₂₀ alkoxy, or alkyl alkoxy.

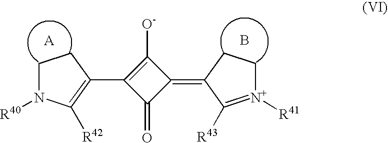

In Formula (VI), A and B are independently phenyl or napthyl. R⁴⁰ and R⁴¹ are independently hydrogen, C₁-C₂₀ alkyl, or alkyl alkoxy. R⁴² and R⁴³ are independently hydrogen, C₁-C₂₀ alkyl, phenyl, or alkyl alkoxy.

In some embodiments, the dye having maximum absorbance at a wavelength ranging from 580 to 600 nm is used in an amount of about 0.01 to about 0.05 wt %, based on the total weight of the composition, which includes the anthraquinone dye, the cyanine dye, the binder resin, and the solvent. However, other embodiments comprise about 0.015 to about 0.045 wt % of the dye having maximum absorbance at a wavelength ranging from 580 to 600 nm based on the total weight of the composition. In other embodiments, the composition comprises about 0.02 to about 0.04 wt % of the dye having maximum absorbance at a wavelength ranging from 580 to 600 nm, based on the total weight of the composition. Some embodiments comprise about 0.005, 0.006, 0.007, 0.008, or 0.009 wt % of the dye having maximum absorbance at a wavelength ranging from 580 to 600 nm, based on the total weight of the composition. In other embodiments, the composition comprises more than about 0.05 wt % of the at least one NIR absorption dye, including about 0.06, 0.07 0.08, 0.09, 0.1, 0.11, 0.12, 0.13, 0.14, or 0.15 wt %, based on the total weight of the composition.

Examples of dyes having maximum absorbance at a wavelength from 580 to 600 nm are commercially available, and include, but are not limited to, TY-102 and TY-171, purchased from Asahi Denka, or HAO-01, purchased from Hayashibara Biochemical.

Aminoanthraquinone Dyes

According to some embodiments, cyanine dyes may be stabilized by the addition of anthraquinone compound which has an amino group substituted at any one position of the anthraquinone compound selected from among 1-, 4-, 5-, and 8-positions, and combinations thereof. Exposure to such dyes to UV and other types of light will not substantially reduce the ability of the cyanine dyes to absorb near infrared or visible wavelengths.

In one embodiment, a composition, which may be a film composition, comprises a cyanine dye exhibiting an absorption maximum in the wavelength region from about 830 to about 880 nm or from about 580 to about 600 nm, and an anthraquinone dye comprising an anthraquinone compound represented by Formula (I):

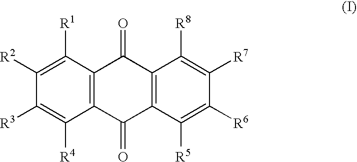

In Formula (I), at least one of R¹, R⁴, R⁵, and R⁸ is NR⁹₂. In some embodiments, R⁹ is independently hydrogen, C₁-C₂₀ alkyl, or aryl. In some embodiments, R², R³, R⁶ and R⁷ are independently hydrogen, halogen, C₁-C₂₀ alkyl, C₁-C₂₀ alkyoxy, aryl, or aryloxy. In some embodiments, when each of R¹, R⁴, R⁵, and R⁸ is not NR⁹₂, each is hydrogen.

As discussed above, the composition comprises an anthraquinone dye. In some embodiments, the anthraquinone dye comprises at least one anthraquinone compound having an amino group substituted at one or more positions selected from the 1-, 4-, 5-, or 8-position.

In certain embodiments, the anthraquinone dye may have a stabilizing effect on the composition. For example, it may increase the light resistance of the composition. In some embodiments, the anthraquinone dye increases the light resistance of the cyanine dye when the cyanine dye is exposed to UV or other light. As compared to other anthraquinone dyes which comprise an anthraquinone compound which is not substituted with an amino group, or even other aminoathraquinone dyes which comprise an anthraquinone compound substituted in a position other than the 1-, 4-, 5,-, or 8-position, the anthraquinone dye as described herein, which is substituted at 1-, 4, 5-, or 8-position, improves the light resistance of the cyanine dye and the overall composition.

In some embodiments, the anthraquinone dye comprises one or more anthraquinone compounds having Formula (I), wherein the anthraquinone compounds are substituted to achieve a color balance in the composition. In some embodiments, it is advantageous to use more than one anthraquinone compound having an amino group substituted at one or more positions selected from among 1-, 4-, 5-, and 8-positions results to improve light resistance of a composition comprising a cyanine dye while not substantially altering the transmittance and color tone of the composition. In some embodiments, the use of more than one anthraquinone dye prevents unbalanced color tones of the composition.

In some embodiments, the appropriate substitution on the anthraquinone compound may generate various colors. In some embodiments, the anthraquinone compound having an amino group substituted at one or more positions selected from among 1-, 4-, 5-, and 8-positions comprises one or more one selected from the group consisting of compounds represented by Formulas VII, VIII, IX, X, or XI.

In one embodiment, the composition comprises at least one anthraquinone compound represented by the following Formula VII:

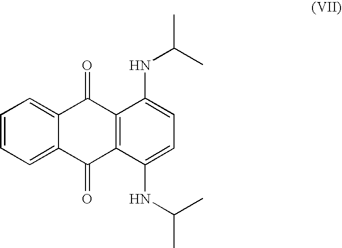

In certain embodiments, the compound represented by Formula VII compensates for wavelengths corresponding to a color that is substantially green

In one embodiment, the composition comprises at least one anthraquinone compound represented by the following Formula VIII.

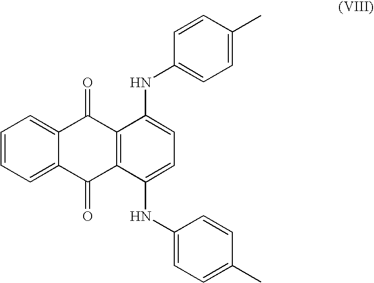

In certain embodiments, the compound represented by Formula VIII compensates for wavelengths corresponding to a color that is substantially green.

In one embodiment, the composition comprises at least one anthraquinone compound represented by the following Formula IX:

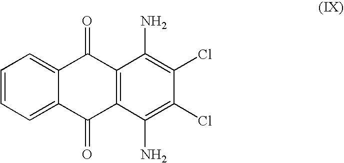

In certain embodiments, the compound represented by Formula IX compensates for wavelengths corresponding to a color that is substantially violet.

In one embodiment, the composition comprises at least one anthraquinone compound represented by the following Formula X:

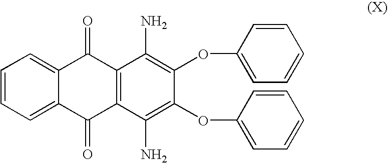

In certain embodiments, the compound represented by Formula X compensates for wavelengths corresponding to a color that is substantially red.

In one embodiment, the composition comprises at least one anthraquinone compound represented by the following Formula XI.

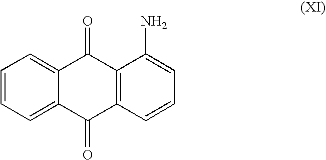

In certain embodiments, the compound represented by Formula XI compensates for wavelengths corresponding to a color that is substantially yellow.

Examples of the anthraquinone dye are commercially available, and include, but are not limited to, Green-5B, Blue-RR, Redvio-RV, Violet-R, or Green-G, each of which may be purchased from M-Dohmen.

In some particular embodiments, the anthraquinone compound is selected from a group consisting of 1,4-bis(isopropylamino)anthracene-9,10-dione, 1,4-bis(p-tolylamino)anthracene-9,10-dione, 1,4-diamino-2,3-dichloroanthracene-9,10-dione, 1,4-diamino-2,3-diphenoxyanthracene-9,10-dione, and 1-aminoanthracene-9,10-dione.

In some embodiments, the anthraquinone dye is about 0.02 to about 0.2 wt %, based on the total weight of the composition, which includes the anthraquinone dye, the cyanine dye, the binder resin and the solvent. However, other embodiments comprise about 0.04 to about 0.18 wt % of the anthraquinone dye, based on the total weight of the composition. In other embodiments, the composition comprises about 0.08 to about 0.15 wt % of the anthraquinone dye, based on the total weight of the composition. Some embodiments comprise about 0.005, 0.008, 0.01, 0.013, or 0.18 wt % of the anthraquinone dye, based on the total weight of the composition. In other embodiments, the composition comprises more than about 0.2 wt % of the anthraquinone dye, including about 0.22, 0.24 0.26, 0.28, or 0.3 wt %, based on the total weight of the composition.

In some embodiments, the composition comprises the anthraquinone dye in an amount from about 100 to about 300 parts by weight, based on 100 parts by weight of the total cyanine dye in the composition. In some embodiments, the anthraquinone dye is about 80 to about 130 parts by weight based on 100 parts by weight of the total cyanine dye in the composition. In other embodiments, the anthraquinone dye is about 120 to about 150 parts by weight based on 100 parts by weight of the total cyanine dye in the composition. In other embodiments, the anthraquinone dye is about 140 to about 170 parts by weight based on 100 parts by weight of the total cyanine dye in the composition. In other embodiments, the anthraquinone dye is about 160 to about 200 parts by weight based on 100 parts by weight of the total cyanine dye in the composition. In other embodiments, the anthraquinone dye is about 180 to about 230 parts by weight based on 100 parts by weight of the total cyanine dye in the composition.

Additional Dye Components

In some embodiments, a composition may additionally comprise at least one diimmonium dye. This dye may function to absorb NIR light at a wavelength from 950 to 1100 nm

In some embodiments, the dimmonium dye is represented by the compound of Formula (XII):

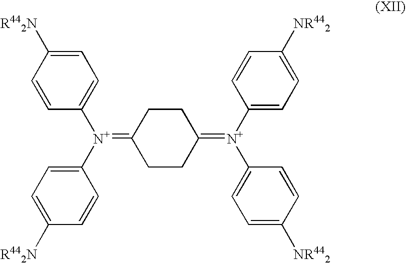

In Formula XII, R⁴⁴ may each be independently selected from an alkyl group having a substituent, an alkenyl group having a substituent, an alkynyl group having a substituent, or an aryl group having a substituent. In some embodiments of the compound represented by Formula XII, the counter ion, which is an anion, is the same anion as that of one of the cyanine dyes of the composition to prevent ion exchange reactions.

In some embodiments, the at least one diimmonium dye is about 0.2 to about 1 wt %, based on the total weight of the composition, which includes the anthraquinone dye, the cyanine dye, the binder resin, and the solvent. However, other embodiments comprise about 0.4 to about 0.8 wt % of the at least one diimmonium dye, based on the total weight of the composition. In other embodiments, the composition comprises about 0.05 to about 0.9 wt % of the at least one diimmonium dye, based on the total weight of the composition. Some embodiments comprise about 0.05, 0.075, 0.1, 0.125, 0.015, or 0.0175 wt % of the at least one diimmonium dye, based on the total weight of the composition. In other embodiments, the composition comprises more than about 1 wt % of the at least one diimmonium dye, including about 1.2, 1.4, 1.6, 1.8, or 2 wt %, based on the total weight of the composition.

Examples of the at least one diimmonium dye are commercially available, and include, but are not limited to, PDC-220, purchased from Nippon Kayaku, or CIR-1085, purchased from Nippon Carlit.

In some embodiments, a composition may additionally comprise at least one toning dye. The at least one toning dye may function to control transmittance of the filter, a color tone balance of RGB, and external color. In some embodiment, it may be used together with the at least one aminoanthraquinone dye to perform any of the above mentioned functions.

In some embodiments, the at least one toning dye comprises one or more selected from the group consisting of a quinophthalone dye, a thioxanthine dye, a methine dye, a perynone dye, an anthraquinone dye, an anthrapyridone dye, a quinacridone dye, and a phthalocyanine dye, but is not limited thereto. In some embodiments, at least one toning dye having high heat resistance and durability may be used for toning a polymer molded body.

In some embodiments, the at least one toning dye is less than about 0.1 wt %, including 0.02, 0.04, 0.06, or 0.08 wt %, based on the total weight of the composition, which includes the anthraquinone dye, the cyanine dye, the binder resin and the solvent. However some embodiment may actually contain an amount greater than or equal to about 0.1 wt %, including about 0.12, 0.14, 0.16, 0.18, and 0.2 wt %.

Examples of toning dyes are commercially available, and include, but are not limited to, Red-A2G, purchased from M-Dohmen, or Yellow-93, purchased from YaBang.

Binder Resin & Solvent

In some embodiments, the composition additionally comprises a binder resin. The binder resin may function to adhere the dyes to a substrate. Although the binder resin is not particularly limited, it may comprise one or more from a group selected from a polycarbonate resin, an acrylic resin, and a polyester resin, but is not limited thereto. In some embodiments, it is advantageous if the binder resin does not react with any component of the coating composition.

In embodiments, the composition also comprises a solvent. In some embodiments, the solvent is mixed with the binder resin. In some embodiments, the solvent is used to dissolve the dyes. A solvent may comprise one or more selected from the group consisting of 2-butanone, 1,3-dioxolane, toluene, ethylacetate, butylacetate, and methylisobutylketone, but is not limited thereto. In some embodiments, a solvent having a higher alkyl moiety is used to ensure that the binder resin does not precipitate out of solution and render the cyanine dye unsuitable.

In one method, a composition is prepared by adding predetermined amounts of the dye components to a solution of binder resin and solvent, and stirring. In order to uniformly apply the above composition on a predetermined surface without coating stains, a composition including one or more dyes, the binder resin, and the solvent may have a viscosity of about 10 to about 100 cps. Other embodiments have a viscosity of about 20 to about 80 cps, and some embodiments have a viscosity of about 30 to about 70 cps. In other embodiments, the composition ratio is controlled to obtain a composition of appropriate viscosity.

In some embodiments, binder resin is about 20 to about 80 wt %, based on the total weight of the composition, which includes the anthraquinone dye, the cyanine dye, the binder resin, and the solvent. Other embodiments comprise about 30 to about 70 wt % of the binder resin, based on the total weight of the composition. In other embodiments, the composition comprises about 35 to about 60 wt % of the solvent, based on the total weight of the composition.

In some embodiments, the solvent is about 20 to about 80 wt %, based on the total weight of the composition, which includes the anthraquinone dye, the cyanine dye, the binder resin, and the solvent. In other embodiments, the solvent comprises about 30 to about 70 wt % of the composition, based on the total weight of the composition. In other embodiments, the composition comprises about 40 to about 60 wt % of the solvent, based on the total weight of the composition.

Application to Substrates

In some embodiments, the composition is applied to a substrate. In some embodiments, the composition may form a film on a substrate. In some embodiments, the substrate may also comprise an antireflective film and an electromagnetic wave shielding film. In some embodiments, one or more films may be directly attached to a display panel using an adhesive, or may be attached to front protective glass.

In one embodiment, a conductive layer formed of a metal or metal oxide may be employed as an electromagnetic wave shielding material of a front filter. In this case, since the conductive layer also acts to absorb near-infrared rays, the composition only needs to contain a cyanine dye having a maximum absorbance at 580 to 600 nm. That is, the composition need not contain a near-infrared absorbing colorant. If the near-infrared absorption function of the conductive layer is not satisfactory, however, a near-infrared absorbing colorant may also be added.

Substrates may also include a transparent polymer film, which is exemplified by a polyethylene terephthalate (PET) film, a polycarbonate (PC) film, and a cyclic olefin copolymer (COC) film, but is not limited thereto. Substrates may also include an at least partially transparent article that can be applied to a display of an electronic device. Some substrates may comprise a transparent surface, such as glass or a polymer film. Some substrates may additionally comprise a filter.

In some embodiments, the composition forms a coating layer on the substrate. In some embodiments, a coating layer having a thickness of about 3 to about 10 μm may be formed on the substrate to obtain a film suitable for filtering certain wavelengths of light for display devices. In some embodiments, the coating layer has substantially the same thickness on the surface of the substrate. In other embodiments, some portion of the substrate may comprise a coating layer that has a different thickness than another portion of the substrate.

One example for use of compositions as described herein is a front filter for a display device. A front filter for use in or on a PDP may comprise an antireflective film to decrease external light reflections, an electromagnetic wave shielding film to block electromagnetic waves, an NIR blocking film to block NIR light, and a color compensating film to increase the color purity of light emitted from a PDP. As such, a single film containing all such dyes may be formed using embodiments of the compositions as described herein.

The invention is further described in terms of the following Examples which are intended for the purpose of illustration and not to be construed as in any way limiting the scope of the present invention, which is defined by the claims. In the following Examples, all parts and percentage are by weight unless otherwise indicated.

### EXAMPLES

### Examples 1-6

### Example 1

### Preparation of a Color Compensating Film Using Anthraquinone Dye and Cyanine Dye

0.06 wt % or 0.12 wt % 1,4-diaminoanthraquinone dye available as Green-5B from M-Dohmen to improve light resistance of a cyanine dye and 0.02 wt % cyanine dye available as HAO-01 from Hayashibara Biochemical to absorb visible light at about 585 nm, based on the total solution were added to a solution of 6.0 g of an acryl polymer binder resin available as GS-1000 from Soken and 4.0 g of 1,3-dioxolane solvent available from Aldrich, with stirring, to prepare a uniform coating solution. Subsequently, the coating solution thus prepared was applied on a primer-treated surface of an optical film available as A4100 from Toyobo, using a wire bar. Thereafter, the coating film was dried using hot air at 80° C. for 1 min, to prepare a film having a color compensating layer 7 μm thick.

### Example 2

### Preparation of a Color Compensating Film Using Anthraquinone Dye and Cyanine Dye (2)

0.06 wt % or 0.12 wt % 1,4-diaminoanthraquinone dye available as Blue-RR from M-Dohmen to improve light resistance of a cyanine dye and 0.02 wt % cyanine dye available as HAO-01 from Hayashibara Biochemical to absorb visible light at about 585 nm, based on the total solution, were added to a solution of 3.5 g of an acryl polymer binder resin available as IR-G205 from Nippon Shokubai and 6.5 g of 2-butanone available from Aldrich, with stirring, to prepare a coating solution. Thereafter, the coating solution thus prepared was applied on a primer-treated surface of an optical film available as A4100 from Toyobo, using a wire bar. Subsequently, the coating film was dried using hot air at 80° C. for 1 min, to prepare a film having a color compensating layer 7 μm thick.

### Example 3

### Preparation of an NIR Absorption Film Using Anthraquinone Dye and Cyanine Dye

0.06 wt % 1,4-diaminoanthraquinone dye available as Blue-AP from YaBang to improve light resistance of a cyanine dye and 0.03 wt % cyanine dye available as TZ-115 from Asahi Denka to absorb NIR at about 850 nm, based on the total solution, were added to a solution of 6.0 g of an acryl polymer binder resin available as GS-1000 from Soken and 4.0 g of toluene, with stirring, to prepare a coating solution. Then, the coating solution was applied on a primer-treated surface of an optical film available as A4100 from Toyobo, using a wire bar. Subsequently, the coating film was dried using hot air at 80° C. for 1 min, to prepare a film having a color compensating layer 7 μm thick.

### Example 4

### Preparation of an NIR Absorption and Color Compensating Film Using Anthraquinone Dye, Cyanine Dye, Diimmonium Dye and Toning Dye

0.015 wt % cyanine dye available as HAO-01 from Hayashibara Biochemical to absorb visible light at about 585 nm, 0.03 wt % cyanine dye available as NK-8758 from Hayashibara Biochemical to absorb NIR light at about 850 nm, 0.4 wt % diimmonium dye available as CIR-1085 from Nippon Carlit to absorb NIR light, 0.04 wt % Redvio-RV available from M-Dohmen, 0.01 wt % Blue-RR available from M-Dohmen, and 0.015 wt % Blue-AP available from YaBang, serving as 1,4-diaminoanthraquinone dye to increase light resistance of a cyanine dye and for toning, and 0.01 wt % Red-A2G available from M-Dohmen and 0.025 wt % Yellow-93 available from YaBang, serving as perynone dye for toning, based on the total solution, were added to a solution of 6.0 g of an acryl polymer resin available as GS-1000 from Soken and 4.0 g of 1,3-dioxolane available from Aldrich, with stirring, to prepare a coating solution. Then, the coating solution thus prepared was applied on a primer-treated surface of an A4100 film available from Toyobo, using a wire bar. Subsequently, the coating film was dried using hot air at 80° C. for 1 min, to prepare a film having a color compensating layer 7 μm thick.

### Example 5

### Preparation of an NIR Absorption and Color Compensating Film Using Anthraquinone Dye, Cyanine Dye, Diimmonium Dye and Toning Dye

0.01 wt % cyanine dye available as TY-171 from Asahi Denka to absorb visible light at about 585 nm, 0.1 wt % phthalocyanine dye available as IR-10A from Nippon Shokubai to block NIR light, 0.4 wt % diimmonium dye available as CIR-1085 from Nippon Carlit to absorb NIR light, 0.04 wt % Redvio-RV available from M-Dohmen, 0.005 wt % Blue-RR available from M-Dohmen, 0.01 wt % Blue-AP available from YaBang, serving as 1,4-diaminoanthraquinone dye to increase light resistance of a cyanine dye and for toning, and 0.005 wt % Red-A2G available from M-Dohmen and 0.045 wt % Yellow-93 available from YaBang, serving as perynone dye for toning, based on the total solution, were added to a solution of 6.0 g of an acryl polymer resin available as GS-1000 from Soken and 4.0 g of 1,3-dioxolane available from Aldrich, with stirring, to prepare a coating solution. Then, the coating solution thus prepared was applied on a primer-treated surface of an A4100 film available from Toyobo, using a wire bar. Subsequently, the coating film was dried using hot air at 80° C. for 1 min, to prepare a film having a color compensating layer 7 μm thick.

### Example 6

### Preparation of an NIR Absorption and Color Compensating Film Using Anthraquinone Dye, Cyanine Dye, Diimmonium Dye and Toning Dye

0.04 wt % tetraazaporphyrin dye available as TAP-2 from Yamada Chemical to absorb visible light at about 590 nm, 0.03 wt % cyanine dye available as PDC-400MC (F) from Nippon Kayaku to absorb NIR light at about 850 nm, 0.4 wt % diimmonium dye available as PDC-220 from Nippon Kayaku to absorb NIR light, 0.06 wt % Redvio-RV available from M-Dohmen and 0.025 wt % Green-G available from M-Dohmen serving as 1,4-diaminoanthraquinone dye to increase light resistance of a cyanine dye and for toning, and 0.005 wt % Red-A2G available from Domen and 0.03 wt % Yellow-93 available from YaBang serving as perynone dye for toning, based on the total solution, were added to a solution of 6.0 g of an acryl polymer resin available as GS-1000 from Soken and 4.0 g of 1,3-dioxolane available from Aldrich, with stirring, to prepare a coating solution. Then, the coating solution thus prepared was applied on a primer-treated surface of an A4100 film available from Toyobo, using a wire bar. Subsequently, the coating film was dried using hot air at 80° C. for 1 min, to prepare a film having a color compensating layer 7 μm thick.

### Comparative Examples 1-3

### Comparative Example 1

### Preparation of a Coating Film Using Perynone Dye and Cyanine Dye

A coating film was prepared in the same manner as in Example 1, with the exception that 0.06 wt % or 0.12 wt % perynone dye available as Orange-HRP from M-Dohmen were used, based on the total solution, instead of Green-5B as 1,4-diaminoanthraquinone dye.

### Comparative Example 2

### Preparation of Coating Film Using 2-Aminoanthraquinone Dye and Cyanine Dye

A coating film was prepared in the same manner as in Example 2, with the exception that 0.10 wt % 2-aminoanthraquinone available from Aldrich, 0.02 wt % cyanine dye HAO-01 available from Hayashibara Biochemical to absorb visible light at about 585 nm, and 0.03 wt % cyanine dye available as TZ-115 from Asahi Denka to absorb NIR light at about 850 nm were used, based on the total solution.

### Comparative Example 3

### Preparation of Coating Film Using Hydroxyanthraquinone Dye and Cyanine Dye

A coating film was prepared in the same manner as in Example 3, with the exception that 0.08 wt % 1,4-dihyroxy anthraquinone available from Aldrich were used, based on the total solution, instead of Blue-AP as 1,4-diaminoanthraquinone dye.

Testing

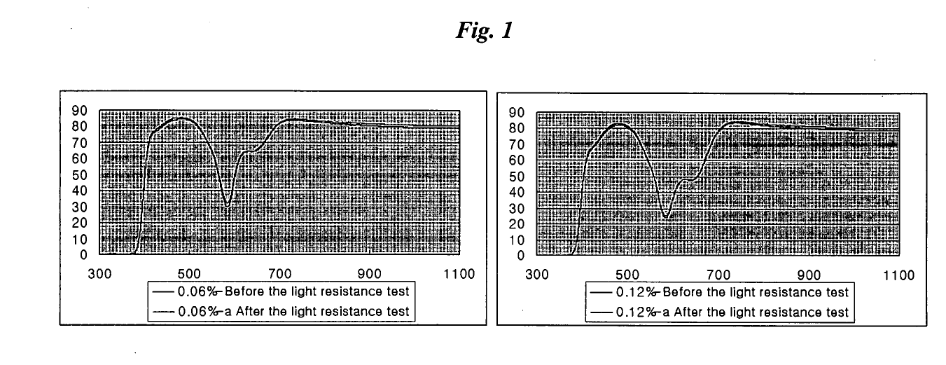

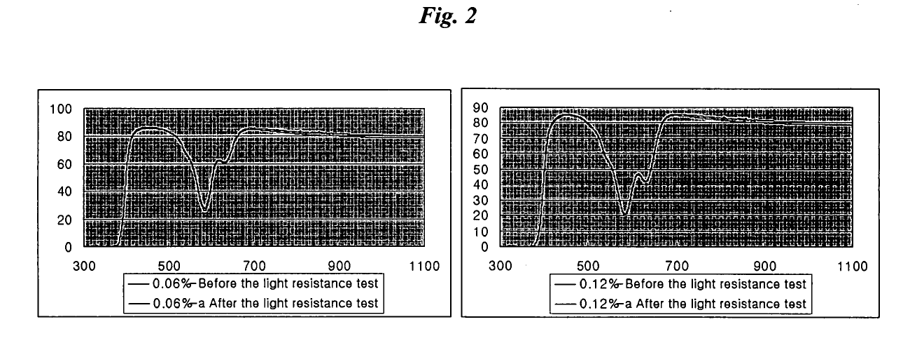

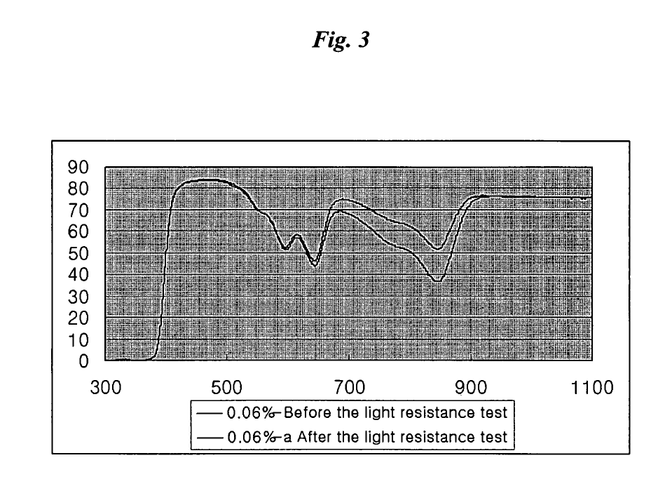

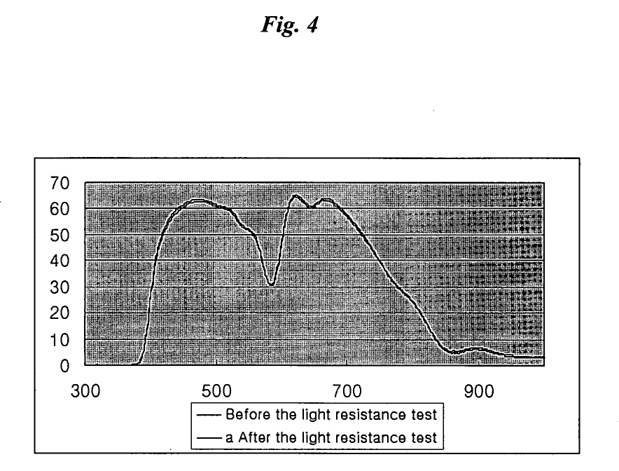

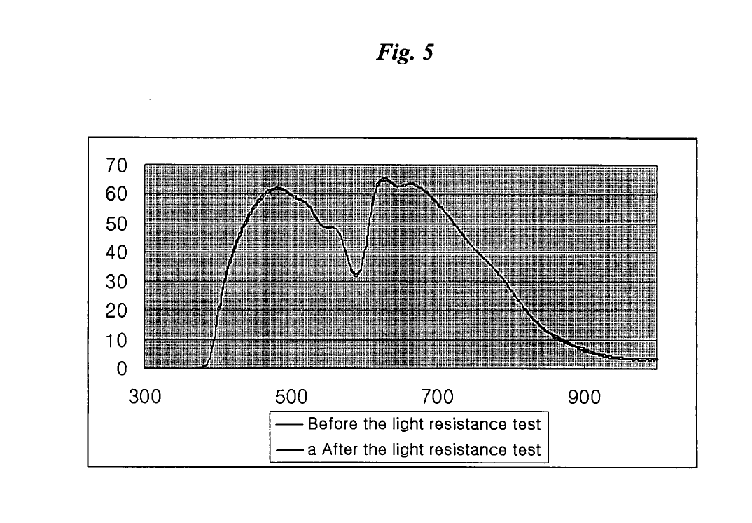

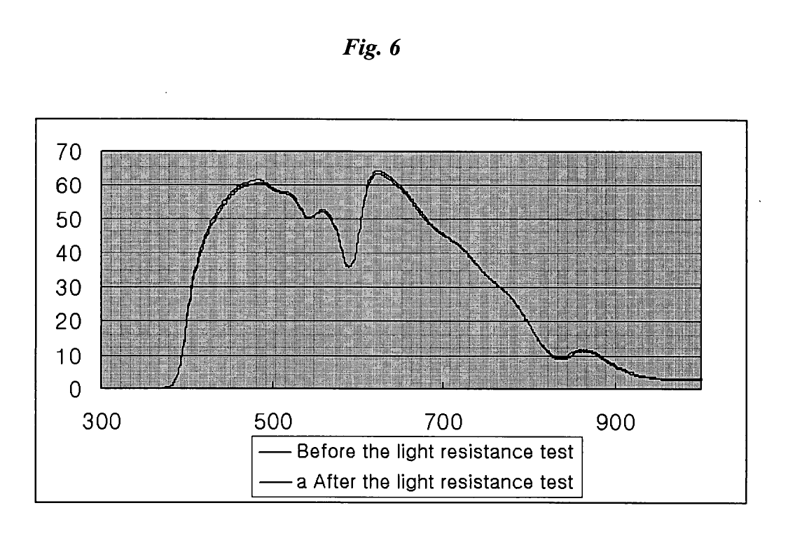

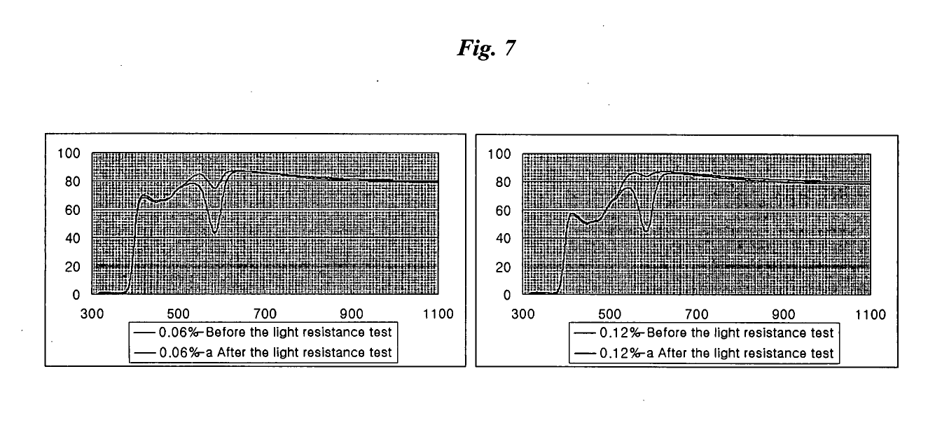

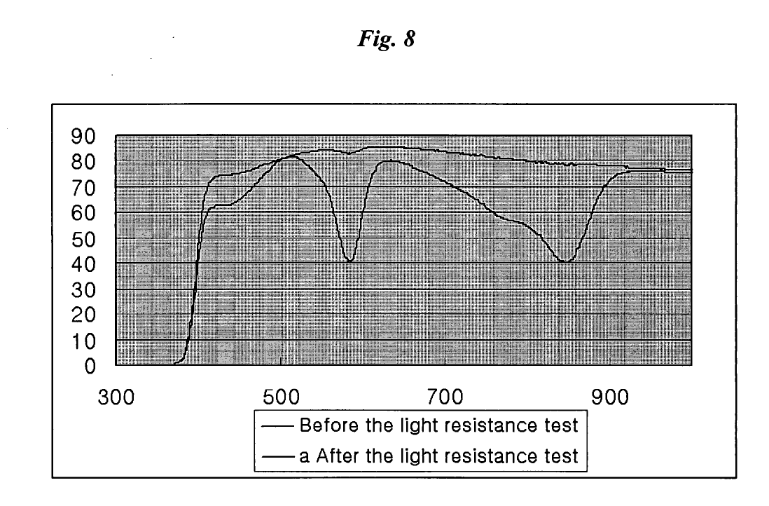

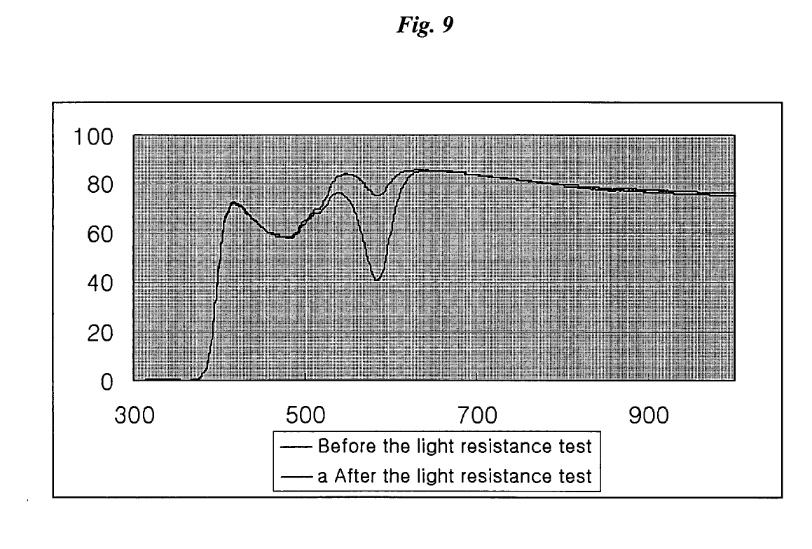

Light resistance of each of the NIR absorption and/or color compensating films prepared in Examples 1-6 and Comparative Examples 1-3 was measured. The results are given in Table 1 below and FIGS. 1 to 9 accompanying.

Light Resistance Test

An adhesive film was attached to the coating surface of each of the coating films prepared in Examples 1-6 and Comparative Examples 1-3, after which the coating film was laminated on a 3 mm thick transparent glass plate, followed by measuring a transmittance spectrum in the specific wavelength range using a Lambda-950 spectrophotometer available from Perkin-Elmer. Thereafter, the coating film was loaded into a Q-panel light resistance tester, and light resistance was tested under the following conditions:

Procedures for radiating UV light onto the film at 60° C. and 0.77 W/m²·nm for 8 hr using a UV-A lamp having an emission peak at 340 nm and then allowing the film to stand at 60° C. for 4 hr for blocking UV light were repeated to reach a total time of 100 hr. Then, the transmission spectrum was measured, to determine a transmittance change at the maximum emission peak of the cyanine dye and a color coordinate change of the transmission spectrum of the whole film.

The results before and after the light resistance test are given in Table 1 below.

TABLE 1

| | Transmittance Change at | |
|---|---|---|
| | Maximum Absorption Peak | Color Coordinate Change |
| | (%) | (dx, dy, dY) |
| Ex. 1-1 (0.06) | 2.2 (585 nm) | (0.0027, 0.0026, 0.51) |
| Ex. 1-2 (0.12) | 0.9 (585 nm) | (0.0018, 0.0016, 0.08) |
| Ex. 2-1 (0.06) | 1.5 (585 nm) | (0.0021, 0.0020, 0.63) |
| Ex. 2-2 (0.12) | 0.9 (585 nm) | (0.0018, 0.0019, 0.33) |
| Ex. 3 | 15.3 (848 nm) | (0.0024, 0.0002, 0.17) |
| Ex. 4 | 0.47 (585 nm) | (0.0012, 0.0010, −0.37) |
| Ex. 5 | 0.65 (585 nm) | (0.0012, 0.0023, −0.07) |
| Ex. 6 | −0.22 (585 nm) | (0.0007, 0.0012, −0.49) |
| C. Ex. 1-1 (0.06) | 31.2 (585 nm) | (0.0179, 0.0175, 10.9) |
| C. Ex. 1-2 (0.12) | 42.2 (585 nm) | (0.0215, 0.0196, 13.5) |
| C. Ex. 2 | 37.9 (848 nm) | (0.019, 0.0039, 15.0) |
| C. Ex. 3 | 34.5 (585 nm) | (0.0189, 0.0190, 12.4) |

As is apparent from Table 1 and FIGS. 1 to 9, the diaminoanthraquinone dye, having an amino group substituted at one or more positions selected from among the 1-, 4-, 5-, and 8-positions, was mixed with the cyanine dye, thereby obtaining an NIR absorption and/or color compensating film having only slightly changed transmittance and color coordinates and high light resistance.

As described hereinbefore, some embodiments include a film for an image display apparatus, comprising an NIR absorption and color compensating layer, and a filter for an image display apparatus using the same. According to some embodiments, light resistance of various cyanine dyes used to absorb NIR and/or compensate color can be substantially increased as compared to dyes that do not utilize the diaminoanthraquinone dye. Some embodiments of a film comprising one or more dyes as described herein may be exposed to strong external light including UV light for a long period of time without substantially decreasing the NIR absorption performance and color compensation performance of the one or more dyes. It is believed that the manufacturing costs of the film and filter for an image display apparatus as described herein are less costly to manufacture than other films and filters.

The skilled artisan will recognize the interchangeability of various features from different embodiments. Similarly, the various features and steps discussed above, as well as other known equivalents for each such feature or step, can be mixed and matched by one of ordinary skill in this art to perform compositions or methods in accordance with principles described herein. Although the invention has been disclosed in the context of certain embodiments and examples, it will be understood by those skilled in the art that the invention extends beyond the specifically disclosed embodiments to other alternative embodiments and/or uses and obvious modifications and equivalents thereof. Accordingly, the invention is not intended to be limited by the specific disclosures of embodiments herein. Rather, the scope of the present invention is to be interpreted with reference to the claims that follow.

What is claimed is:

1. A composition for use in a plasma display device comprising:
a cyanine dye exhibiting an absorption maximum in the wavelength region from about 830 to about 880 nm or from about 580 to about 600 nm; and
an anthraquinone dye comprising an anthraquinone compound represented by Formula (I): 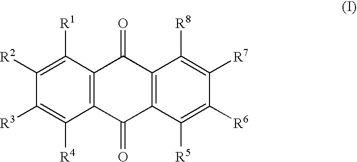
wherein at least one of R¹, R⁴, R⁵, and R⁸ is NR⁹₂;
wherein R², R³, R⁶ and R⁷ are independently hydrogen, halogen, C₁-C₂₀ alkyl, C₁-C₂₀ alkyoxy, aryl, or aryloxy; and
wherein R⁹ is independently hydrogen, C₁-C₂₀ alkyl, or aryl.

2. The composition of claim 1, wherein when each of R¹, R⁴, R⁵, and R⁸ is not NR⁹₂, each is hydrogen.

3. The composition of claim 1, wherein the cyanine dye is represented by Formula (II) 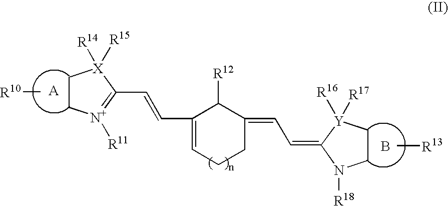
wherein R¹⁰ and R¹³ are independently hydrogen, halogen, nitro, cyano, C₁-C₂₀ alkoxy, C₁-C₂₀ alkyl, alkyl alkoxy, or amino,
wherein R¹¹ and R¹⁸ are independently hydrogen, C₁-C₂₀ alkyl, alkyl alkoxy, or alkyl sulfonic,
wherein R¹² is hydrogen, halogen, substituted phenyl, C₁-C₂₀ alkyl, or amino,
wherein R¹⁴, R¹⁵, R¹⁶, and R¹⁷ are independently hydrogen, C₁-C₂₀ alkyl, or cyclic alkyl
wherein R¹⁴, R¹⁵, R¹⁶, and R¹⁷ may be cyclic alkyl, wherein R¹⁴ and R¹⁵ or R¹⁶ and R¹⁷ are connected through a membered ring comprising three or more carbon atoms,
wherein A and B are independently phenyl, napthyl, or anthracenyl,
wherein X and Y are independently C, N, S or Se,
wherein when X or Y is N, then R¹⁵ or R¹⁷ is not present,
wherein when X or Y is S or Se, then R¹⁴, R¹⁵, R¹⁶, or R¹⁷ is not present, and
wherein n is 0, 1 or 2.

4. The composition of claim 1, wherein the cyanine dye is represented by the Formula (III): 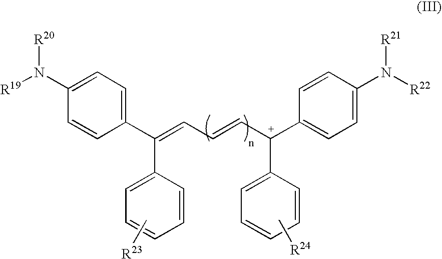
wherein R¹⁹, R²⁰, R²¹, and R²² are independently hydrogen, C₁-C₂₀ alkyl, C₁-C₂₀ alkoxy, alkyl alkoxy group,
wherein R¹⁹, R²⁰, R²¹, and R²² may be cyclic alkyl wherein R¹⁹ and R²⁰ or R²¹ and R²² are connected through a membered ring comprising three or more carbon atoms,
wherein R²³ and R²⁴ are independently hydrogen, halogen, nitro, cyano, C₁-C₂₀ alkoxy, C₁-C₂₀ alkyl, alkyl alkoxy, or amino, and
wherein n is 0, 1, 2, 3 or 4.

5. The composition of claim 1, wherein the cyanine dye is represented by the Formula (IV): 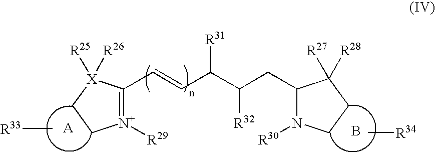
wherein R³³ and R³⁴ are independently hydrogen, halogen, nitro, cyano, C₁-C₂₀ alkoxy, C₁-C₂₀ alkyl, alkyl alkoxy, or amino,
wherein R²⁹ and R³⁰ are independently hydrogen, C₁-C₂₀ alkyl, alkyl alkoxy, or alkylsulfonic acid group,
wherein n is 0 or 1,
wherein when n is 0, R³¹ is hydrogen, and R³² is hydrogen, halogen, aryl, C₁-C₂₀ alkyl, or amino,
wherein when n is 1, R³¹ is hydrogen, halogen, aryl, C₁-C₂₀ alkyl, or amino, and R³² is hydrogen.
wherein A and B are independently phenyl, napthyl, or anthracenyl,
wherein X and Y are independently C, N, S, or Se.
wherein when X or Y is C, then R²⁵, R²⁶, R²⁷, and R²⁸ are independently hydrogen, C₁-C₂₀ alkyl, or cyclic alkyl wherein R²⁵ and R²⁶ or R²⁷ and R²⁸ are connected through a membered ring comprising three or more carbon atoms,
wherein when X or Y is N, then R²⁶ or R²⁸ is not present, and R²⁵ and R²⁶ are independently hydrogen or C₁-C₂₀ alkyl,
wherein when X or Y is S or Se, then R¹ and R² are not present, or R³ and R⁴ is not present.

6. The composition of claim 1, wherein the cyanine dye is represented by Formula (V): 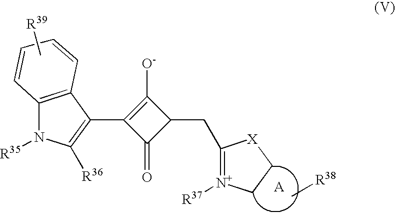
wherein A is independently phenyl or napthyl,
wherein R³⁵ and R³⁷ are independently hydrogen, C₁-C₂₀ alkyl, alkyl alkoxy, or an alkylsulfonic acid group,
wherein R³⁶ is hydrogen, C₁-C₂₀ alkyl, phenyl, or alkyl alkoxy, and
wherein R³⁸ and R³⁹ are independently hydrogen, halogen, nitro, cyano, C₁-C₂₀ alkyl, C₁-C₂₀ alkoxy, or alkyl alkoxy.

7. The composition of claim 1, wherein the cyanine dye comprises a compound having Formula (VI) 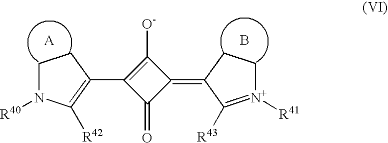
wherein A and B are independently phenyl or napthyl
wherein R⁴⁰ and R⁴¹ are independently hydrogen, C₁-C₂₀ alkyl, or alkyl alkoxy, and
wherein R⁴² and R⁴³ are independently hydrogen, C₁-C₂₀ alkyl, phenyl, or alkyl alkoxy.

8. The composition of claim 1, wherein the anthraquinone compound is selected from a group consisting of 1,4-bis(isopropylamino)anthracene-9,10-dione, 1,4-bis(p-tolylamino)anthracene-9,10-dione, 1,4-diamino-2,3-dichloroanthracene-9,10-dione, 1,4-diamino-2,3-diphenoxyanthracene-9,10-dione, and 1-aminoanthracene-9,10-dione.

9. The composition of claim 1, further comprising a dye exhibiting an absorption maximum in the wavelength region from about 950 to about 1100 nm.

10. The composition of claim 9, wherein the dye exhibiting an absorption maximum in the wavelength region from about 950 to about 1100 nm comprises a diimmonium dye.

11. The composition of claim 1, further comprising a toning dye.

12. The composition of claim 1, further comprising a binder resin and a solvent.

13. The composition of claim 1, wherein the composition is formed in a layer on a substrate.

14. A filter comprising the composition of claim 1.

15. An electronic device comprising:
a display configured to display a visible image on a display surface; and
a film covering at least part of the display surface;
wherein the film comprises the composition of claim 1.

16. A method of displaying an image using the electronic device of claim 15 comprising:
providing the electronic device of claim 15;
stimulating the electronic device so as to emit near infrared light from the display; and
wherein at least part of the near infrared light emitted from the display is absorbed in the film.

17. The method of claim 16, wherein the electronic device is configured to further emit orange light having a wavelength of about 580 nm to about 600 nm; and wherein the filter is configured to further absorb at least part of the orange light.

18. A method of preventing the malfunction of electronic devices that operate in accordance with a wireless signal carried by near infrared light, the method comprising:
providing a display device emitting near infrared light, wherein the display device comprises a display surface, and
covering at least part of the display surface with a filter comprising the composition of claim 1,
wherein the filter absorbs at least part of the near infrared light that causes the malfunction of an electronic device.

19. The method of claim 18, wherein the electronic device is selected from the group consisting of a DVD player, a CD player, a remote control of an electronic device, a DVR recorder, a stereo system, and a microwave oven.

20. The method of claim 18, wherein the display device comprises a plasma display device.
